(19) United States
(12) Patent Application Publication
(10) Pub. No.: US 2018/0226605 A1
(43) Pub. Date: Aug. 9, 2018

(54) GAS BARRIER FILM, ORGANIC ELECTRONIC DEVICE, SUBSTRATE FOR ORGANIC ELECTROLUMINESCENCE DEVICE, AND ORGANIC ELECTROLUMINESCENCE DEVICE

(71) Applicant: FUJIFILM Corporation, Tokyo (JP)

(72) Inventor: Aya NAKAYAMA, Ashigarakami-gun (JP)

(73) Assignee: FUJIFILM Corporation, Tokyo (JP)

(21) Appl. No.: 15/947,031

(22) Filed: Apr. 6, 2018

Related U.S. Application Data
(63) Continuation of application No. PCT/JP2016/079220, filed on Oct. 3, 2016.

(30) Foreign Application Priority Data
Oct. 9, 2015 (JP) 2015-200796

(51) Int. Cl. H01L 51/52; H01L 51/50

(52) U.S. Cl. CPC H01L 51/524; H01L 51/5056; H01L 51/5072; H01L 51/5012; H01L 51/5206; H01L 51/5221; H01L 51/5096

(57) ABSTRACT

A gas barrier film includes a film substrate, an inorganic layer, and a protective layer that is in direct contact with the inorganic layer and is provided on a surface of the inorganic layer, in this order, in which the protective layer is a layer formed by curing a composition including a (meth)acrylate having a carbon ring and a (meth)acrylic polymer. The organic electronic device, a substrate for an organic electroluminescence device, and an organic electroluminescence device include the gas barrier film.

### CROSS-REFERENCE TO RELATED APPLICATIONS

This application is a Continuation of PCT International Application No. PCT/JP2016/079220, filed on Oct. 3, 2016, which claims priority under 35 U.S.C. § 119(a) to Japanese Patent Application No. 2015-200796, filed on Oct. 9, 2015. Each of the above application(s) is hereby expressly incorporated by reference, in its entirety, into the present application.

### BACKGROUND OF THE INVENTION

### 1. Field of the Invention

The present invention relates to a gas barrier film. The present invention also relates to an organic electronic device, a substrate for an organic electroluminescence device, and an organic electroluminescence device using a gas barrier film.

### 2. Description of the Related Art

As a gas barrier film having a function of blocking water vapor, oxygen, and the like, a gas barrier film in which an inorganic layer is provided on a plastic film as a substrate has been developed as a film having high barrier properties from various viewpoints. Since a gas barrier film is light in weight and has impact resistance, it is possible to provide a flexible organic electronic device using the gas barrier film as a substrate or a sealing member of an organic electronic device (for example, refer to JP2005-251500A and JP2009-172991A).

### SUMMARY OF THE INVENTION

In a substrate for an organic electronic element described in JP2005-251500A, an organic electronic element is formed such that a gas barrier film is provided such that an inorganic layer becomes the outermost surface with respect to the organic electronic element side and the inorganic layer and an electrode layer in the organic electronic element are adjacent to each other. With such a configuration, the effect of moisture on the organic electronic element can be suppressed at a low level. However, the inorganic layer is likely to be damaged and the barrier properties of the gas barrier film in which the inorganic layer is disposed as the outermost surface are deteriorated in some cases due to damage. In order to prevent damage, it is considered to provide a protective layer. However, there is a problem that the moisture included in the protective layer causes deterioration of the organic electronic element. In addition, in a case of forming an organic layer such as a protective layer on the surface of the inorganic layer, a silane coupling agent is usually added to the organic layer to improve the adhesiveness of both layers. However, the organic layer including the silane coupling agent is likely to contain moisture and thus it is not preferable to use the organic layer as a substrate or a sealing member of an organic electronic device.

On the other hand, JP2009-172991A discloses a gas barrier film including an organic layer having a water absorption rate of less than 1.0%. However, in JP2009-172991A, the formation of the organic layer on the outermost surface of a gas barrier film is not specifically disclosed. In the technique described in JP2009-172991A, the water absorption rate of the organic layer is adjusted to suppress crack generation in the inorganic layer due to a change in volume of the organic layer of the gas barrier film, and problems in a case where the organic layer is used as a protective layer are not shown in JP2009-172991A. In a case where the organic layer is disposed as the outermost surface and is used as a substrate or a sealing member of an organic electronic device, further, with adjustment of a high moisture content or the like, it is required to study adhesiveness between the organic layer and a functional layer such as an electrode or an adhesive layer to be provided on the surface thereof. Thus, in JP2009-172991A, a configuration in which the gas barrier film having the organic layer disposed as the outermost surface is used in an organic electronic device is not disclosed.

An object of the present invention is to provide a gas barrier film having a surface with high scratch resistance and low moisture release and exhibiting good adhesiveness in a case where a functional layer is provided on the surface thereof. Another object of the present invention is to provide an organic electronic device, particularly, an organic electroluminescence device, an organic electronic element of which is less likely to be deteriorated.

The present inventors have conducted intensive studies for achieving the above objects and further conducted studies particularly on the composition of a protective layer. Thus, the present invention has been completed.

That is, the present invention provides the following [1] to [16].
[1] A gas barrier film comprising, in order: a film substrate; an inorganic layer; and a protective layer that is in direct contact with the inorganic layer and is provided on a surface of the inorganic layer, in which the protective layer is a layer formed by curing a composition including a (meth)acrylate having a carbon ring and a (meth)acrylic polymer.
[2] The gas barrier film according to [1], in which the (meth)acrylate has two or more (meth)acryloyl groups.
[3] The gas barrier film according to [1] or [2], in which the (meth)acrylate has a fluorene ring.
[4] The gas barrier film according to any one of [1] to [3], in which a weight-average molecular weight of the (meth)acrylic polymer is 20,000 or more and 600,000 or less.
[5] The gas barrier film according to any one of [1] to [4], in which an amount of the (meth)acrylic polymer is 5% to 40% by mass with respect to a total mass of solid contents of the composition.
[6] The gas barrier film according to any one of [1] to [4], in which an amount of the (meth)acrylic polymer is 10% to 30% by mass with respect to a total mass of solid contents of the composition.
[7] The gas barrier film according to any one of [1] to [6], in which the composition includes a silane coupling agent.
[8] The gas barrier film according to any one of [1] to [7], in which a film thickness of the protective layer is 0.1 to 2.0 μm.
[9] The gas barrier film according to any one of [1] to [8], in which the inorganic layer includes oxynitride silicon or silicon nitride.
[10] The gas barrier film according to any one of [1] to [9], further comprising: at least one organic layer between the film substrate and the inorganic layer.
[11] The gas barrier film according to any one of [1] to [10], in which at least two organic layers and at least two inorganic layers are provided, and the film substrate, one organic layer, one inorganic layer, the other organic layer, the other inorganic layer, and the protective layer are provided in this order.
[12] An organic electronic device comprising: the gas barrier film according to any one of [1] to [11].
[13] A substrate for an organic electroluminescence device comprising: the gas barrier film according to any one of [1] to [11]; and an organic electroluminescent element that is in direct contact with the protective layer.
[14] The substrate for an organic electroluminescence device according to [13], in which the organic electroluminescent element includes an anode, a light emitting layer, and a cathode in this order, and the anode is formed by coating.
[15] An organic electroluminescence device comprising: the substrate for an organic electroluminescence device according to [13] or [14].
[16] An organic electroluminescence device comprising, in order: a substrate; an organic electroluminescent element that is provided on the substrate; and the gas barrier film according to any one of [1] to [11], in which a surface of the gas barrier film on an organic electroluminescent element side is the protective layer.

According to the present invention, a gas barrier film having a surface with high scratch resistance and low moisture release and exhibiting good adhesiveness in a case where a functional layer is provided on the surface thereof is provided. It is possible to provide a substrate for an organic electronic element and an organic electronic device, an organic electronic element of which is less likely to be deteriorated using the gas barrier film of the present invention.

### DESCRIPTION OF THE PREFERRED EMBODIMENTS

Hereinafter, the contents of the present invention will be described in detail. In the present specification, “to” is used to mean that numerical values described before and after “to” are included in a numerical range as a lower limit value and an upper limit value. In the present specification, “(meth)acrylate” represents “either or both of acrylate and methacrylate”. The same shall be applied to “(meth)acrylic polymer”, “(meth)acryloyl group”, and the like.

<Gas Barrier Film>

A gas barrier film of the present invention includes a film substrate, an inorganic layer, and a protective layer in this order. The gas barrier film of the present invention may further include other layers. For example, it is preferable that the gas barrier film further includes an organic layer other than the protective layer. The gas barrier film of the present invention may include two or more inorganic layers or may be formed by alternately laminating two or more organic layers and two or more inorganic layers.

Preferable examples of the layer configuration of the gas barrier film include the followings. The layers are laminated in the described orders of film substrate/inorganic layer/protective layer; film substrate/organic layer/inorganic layer/protective layer; film substrate/inorganic layer/organic layer/inorganic layer/protective layer; film substrate/organic layer/inorganic layer/organic layer/inorganic layer/protective layer; and film substrate/inorganic layer/organic layer/inorganic layer/organic layer/inorganic layer/protective layer. More preferably, the gas barrier film has at least two organic layers and at least two inorganic layers, and has a film substrate, an organic layer, an inorganic layer, an organic layer, an inorganic layer, and a protective layer in this order.

The number of layers constituting the gas barrier film is not particularly limited, but the number of layers is typically preferably 3 to 20 and more preferably 3 to 10. The gas barrier film of the present invention may have a functional layer other than the film substrate, the organic layer, the inorganic layer, and the protective layer. The functional layer is described in detail in paragraphs 0036 to 0038 of JP2006-289627A. Examples of functional layers other than these functional layers include a matting agent layer, a solvent resistant layer, an antistatic layer, a flattening layer, an adhesiveness improving layer, a light shielding layer, an antireflection layer, a hard coat layer, a stress relaxing layer, an antifogging layer, an antifouling layer, and a layer to be printed.

The film thickness of the gas barrier film is preferably 10 μm to 200 μm and more preferably 20 μm to 150 μm.

[Film Substrate]

The film substrate (hereinafter, also simply referred to as a “substrate”) may be a plastic film. The plastic film to be used is not particularly limited in terms of a material, thickness, or the like as long as the film can hold a laminate including an inorganic layer and a protective layer to be provided thereon and can be selected appropriately depending on the purpose of use or the like. Specifically, the plastic film includes thermoplastic resins such as polyester resin such as polyethylene terephthalate (PET), methacrylic resin, methacrylic acid-maleic acid copolymer, polystyrene resin, transparent fluorine-containing resin, polyimide, fluorinated polyimide resin, polyamide resin, polyamide-imide resin, polyetherimide resin, cellulose acylate resin, polyurethane resin, polyether ether ketone resin, polycarbonate resin, alicyclic polyolefin resin, polyarylate resin, polyether sulfone resin, polysulfone resin, cycloolefin copolymer, fluorene ring-modified polycarbonate resin, alicyclic-modified polycarbonate resin, fluorene ring-modified polyester resin, and acryloyl compound. As the film substrate, polyester resin can be particularly preferably used.

The film thickness of the film substrate is preferably 8 μm to 200 μm and more preferably 18 μm to 150 μm.

[Inorganic Layer]

The inorganic layer is typically a thin film layer including a metal compound. As a method of forming the inorganic layer, any method can be used as long as the desired thin film can be formed. Examples of the method include physical vapor deposition methods (PVD) such as a vapor deposition method, a sputtering method and an ion plating method, various chemical vapor deposition methods (CVD), and liquid phase growth methods such as plating and a sol-gel method. The inorganic layer is preferably formed by a chemical vapor deposition method. The inorganic layer formed by a chemical vapor deposition method has a smooth surface and thus the adhesiveness with the organic layer provided on the surface thereof may be reduced. In the gas barrier film of the present invention, even in a case where the inorganic layer formed by a chemical vapor deposition method is used as the surface on which the protective layer is provided, sufficient intimate attachment between the protective layer and the inorganic layer can be obtained.

Components included in the inorganic layer are not particularly limited as long as the components satisfy a gas barrier performance. Examples of the components include a metal oxide, a metal nitride, a metal carbide, a metal oxynitride and a metal oxycarbide, and an oxide, a nitride, a carbide, an oxynitride, an oxycarbide or the like containing one or more metals selected from Si, Al, In, Sn, Zn, Ti, Cu, Ce, and Ta can be used preferably. Among these, an oxide, a nitride or an oxynitride of a metal selected from Si, Al, In, Sn, Zn, and Ti is preferable, particularly, an oxide of Si, a nitride of Si, an oxynitride of Si, an oxide of Al, a nitride of Al, or an oxynitride of Al is preferable. These may contain another element as a subcomponent.

As the inorganic layer, particularly, inorganic layers including silicon (Si) are preferable. This is because the inorganic layers have higher transparency and further excellent gas barrier properties. Among these, an inorganic layer including oxynitride silicon or silicon nitride is particularly preferable.

For example, the inorganic layer may include hydrogen since an oxide, a nitride, or an oxynitride of a metal contains hydrogen. However, the hydrogen concentration in Rutherford forward scattering is preferably 30% or less.

The smoothness of the inorganic layer is preferably less than 3 nm and more preferably 1 nm or less as an average roughness in 1 μm square (a square having one side of 1 μm) (Ra value).

The thickness of the inorganic layer is not particularly limited. Typically, the thickness of the single inorganic layer is in a range of 5 to 500 nm, preferably 10 to 200 nm, and more preferably 15 to 50 nm. The single inorganic layer may have a laminated structure having a plurality of sub-layers. In this case, the respective compositions of each sub-layer may be the same as or different from each other.

In a case where the gas barrier film of the present invention includes two or more inorganic layers, the compositions, formation methods, film thicknesses, and the like of each inorganic layer may be the same as or different from each other. The compositions of each inorganic layer are preferably the same as each other and the compositions and formation methods thereof are more preferably the same as each other.

[Protective Layer]

The gas barrier film of the present invention has a protective layer on the surface thereof. The protective layer may be formed on at least one surface of the gas barrier film. By providing the protective layer on the surface, high scratch resistance is obtained in the gas barrier film of the present invention and particularly, the inorganic layer related to barrier properties can be protected. In the gas barrier film of the present invention, the protective layer is in direct contact with at least one inorganic layer in the gas barrier film.

The protective layer is a kind of organic layer which will be described later, but in the present specification, the protective layer refers to an organic layer that is provided on at least one surface of the gas barrier film to be in direct contact with the inorganic layer. Further, the protective layer has the properties and compositions described later. In the present specification, the organic layer and the protective layer are used separately.

By using a composition for forming a protective layer described later, a protective layer having a moisture content of less than 1.0% can be formed as the protective layer in the gas barrier film of the present invention. By providing such a protective layer, a surface with low moisture release can be provided to the gas barrier film. The moisture content is preferably 0.7% or less, more preferably 0.6% or less, and even more preferably 0.5% or less. In the present specification, the moisture content is a value obtained by a Karl Fischer method according to the description of JIS K0113. In addition, the moisture content is a value measured after the protective layer is dried overnight in a vacuum oven at 0.133 Pa (1×10⁻³ torr) and 110° C. and then is left to stand under the environment of 25° C. and 50% relative humidity (RH) for 3 days.

As described later, the protective layer in the gas barrier film of the present invention has high adhesiveness with the inorganic layer, high scratch resistance, and high solvent resistance as well as a low moisture content.

The film thickness of the protective layer is preferably 0.1 to 2.0 μm and more preferably 0.2 to 1.6 μm.

[Composition for Forming Protective Layer]

The protective layer in the gas barrier film of the present invention is a layer formed by curing a composition including (meth)acrylate having a carbon ring and (meth)acrylic polymer. In the present specification, the composition is sometimes referred to as a “composition for forming a protective layer”. For example, the formation of the protective layer using the composition for forming a protective layer can be performed by applying the composition for forming a protective layer to the surface of the inorganic layer and curing the coating film. Specifically, the formation of the protective layer may be performed in the same manner as in the formation of the organic layer using a composition for forming an organic layer which will be described later.

((Meth)Acrylate Having Carbon Ring)

The carbon ring may be any of a saturated hydrocarbon ring and an unsaturated hydrocarbon ring. In addition, the carbon ring may be a monocyclic ring or may be a fused ring or a spiro ring. The number of carbon atoms included in the carbon ring is not particularly limited and is preferably 3 to 12 and more preferably 5 to 10. Specific examples of the carbon ring include a cycloalkane ring such as cyclohexane ring, a benzene ring, a naphthalene ring, a fluorene ring, an anthracene ring, or a phenanthrene ring. Among these, a benzene ring or a fluorene ring is preferable, and a fluorene ring is particularly preferable. The (meth)acrylate having a carbon ring may have only one carbon ring or may have two or more carbon rings such as two, three, or four carbon rings. The two or more carbon rings may be the same as or different from each other. For example, (meth)acrylate including two or more benzene rings, (meth)acrylate including a benzene ring and a fluorene ring, and the like may be used. As a preferable example, (meth)acrylate including a biphenyl structure or a 9,9-bisphenylfluorene structure may also be used.

The (meth)acrylate having a carbon ring may have one or more (meth)acryloyl groups and preferably has two or more (meth)acryloyl groups.

Specific examples of the (meth)acrylate having a carbon ring include compounds described in JP2010-30290A (particularly, compounds described in paragraphs 0017 and 0018), compounds described in JP2010-30292A (particularly, compounds described in paragraphs 0013, 0019, and 0020), and compounds described in paragraphs 0014 to 0017 of JP2011-51194A.

As the (meth)acrylate having a carbon ring, specifically, the follows can be exemplified, but the (meth)acrylate having a carbon ring is not limited to these examples. In the chemical formulae of (meth)acrylates having a carbon ring exemplified below, n represents an integer.

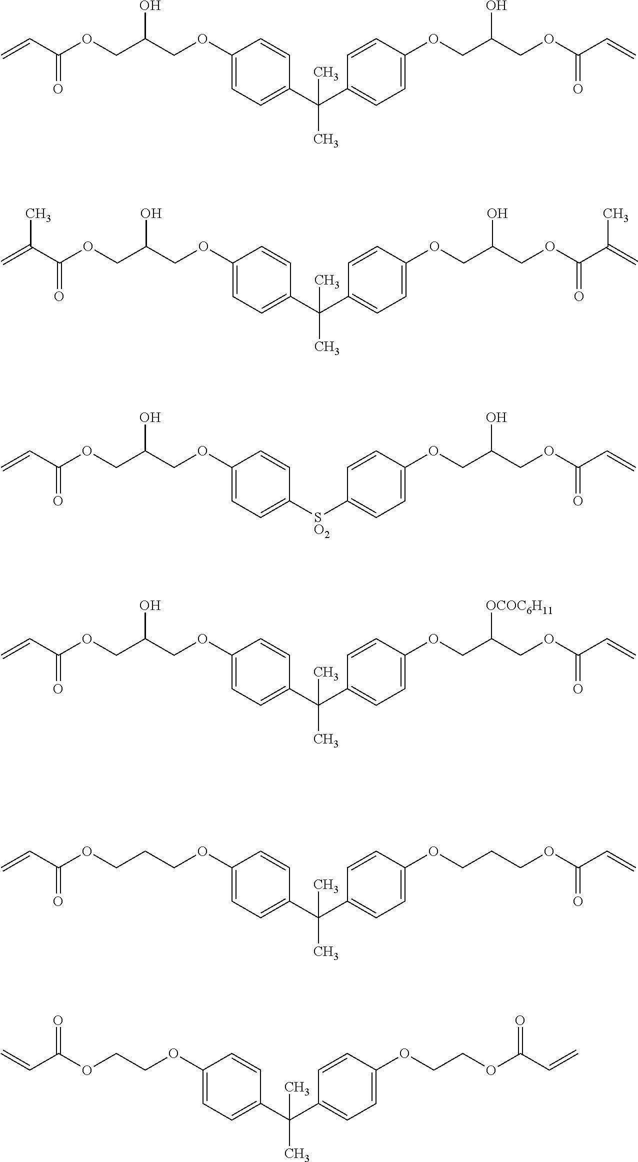

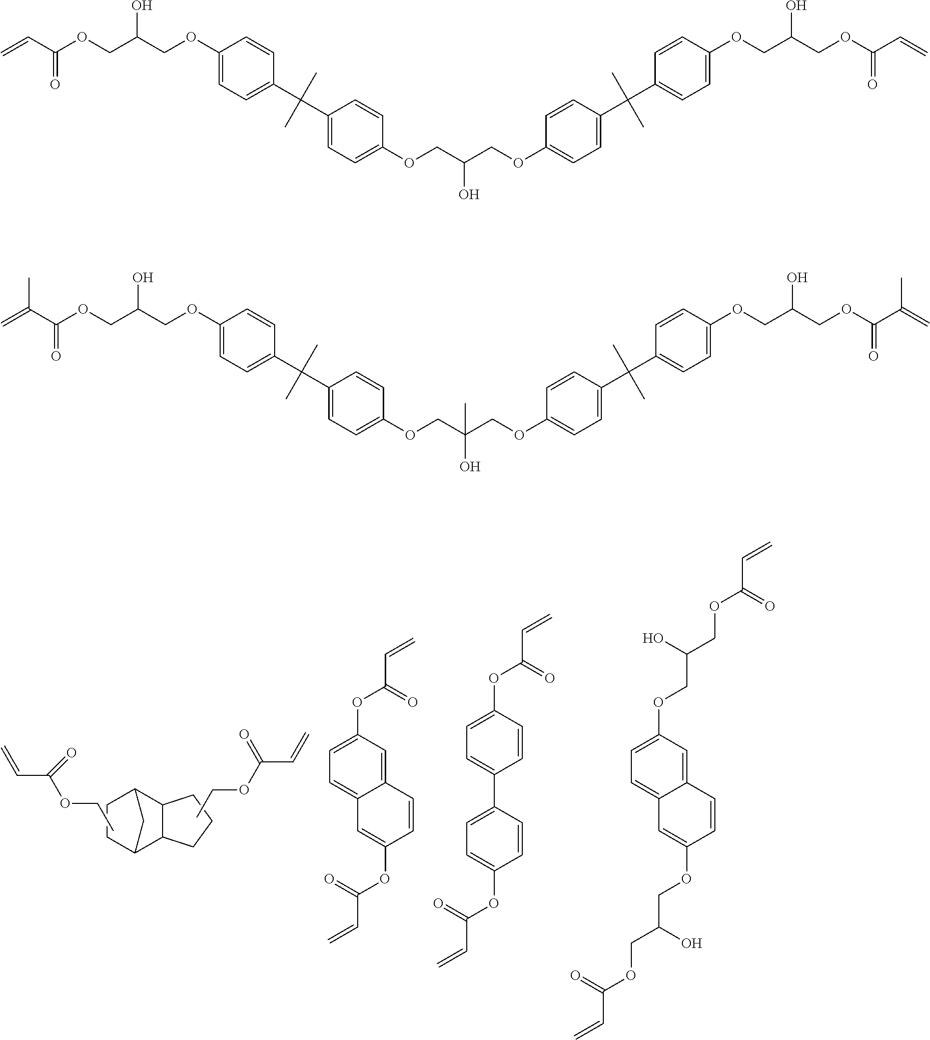

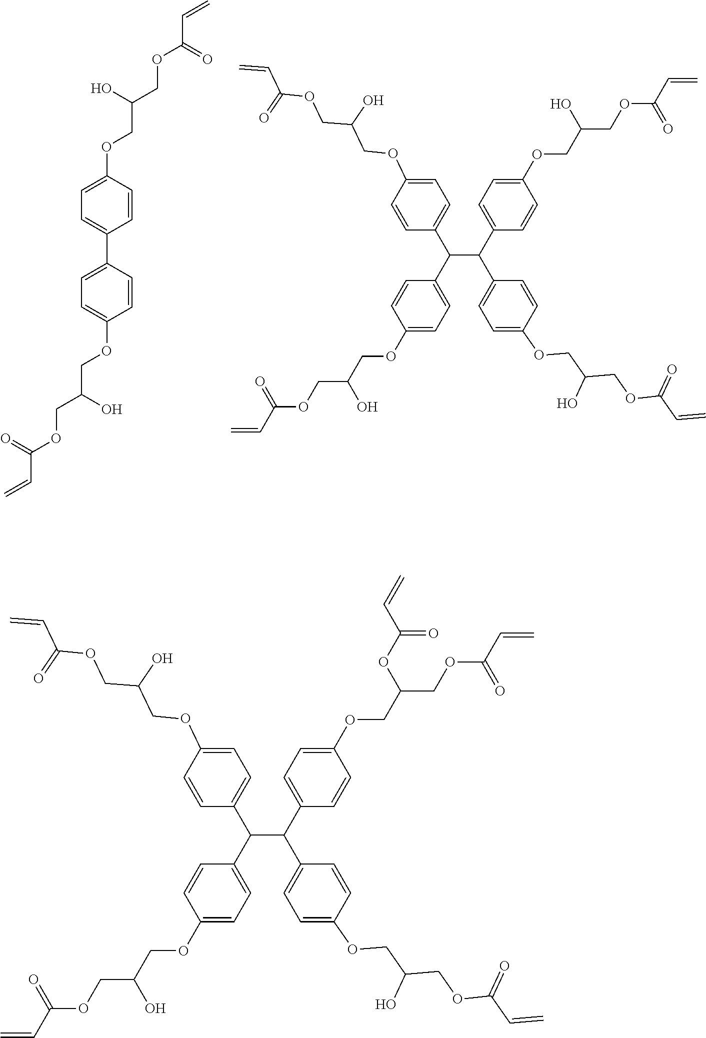

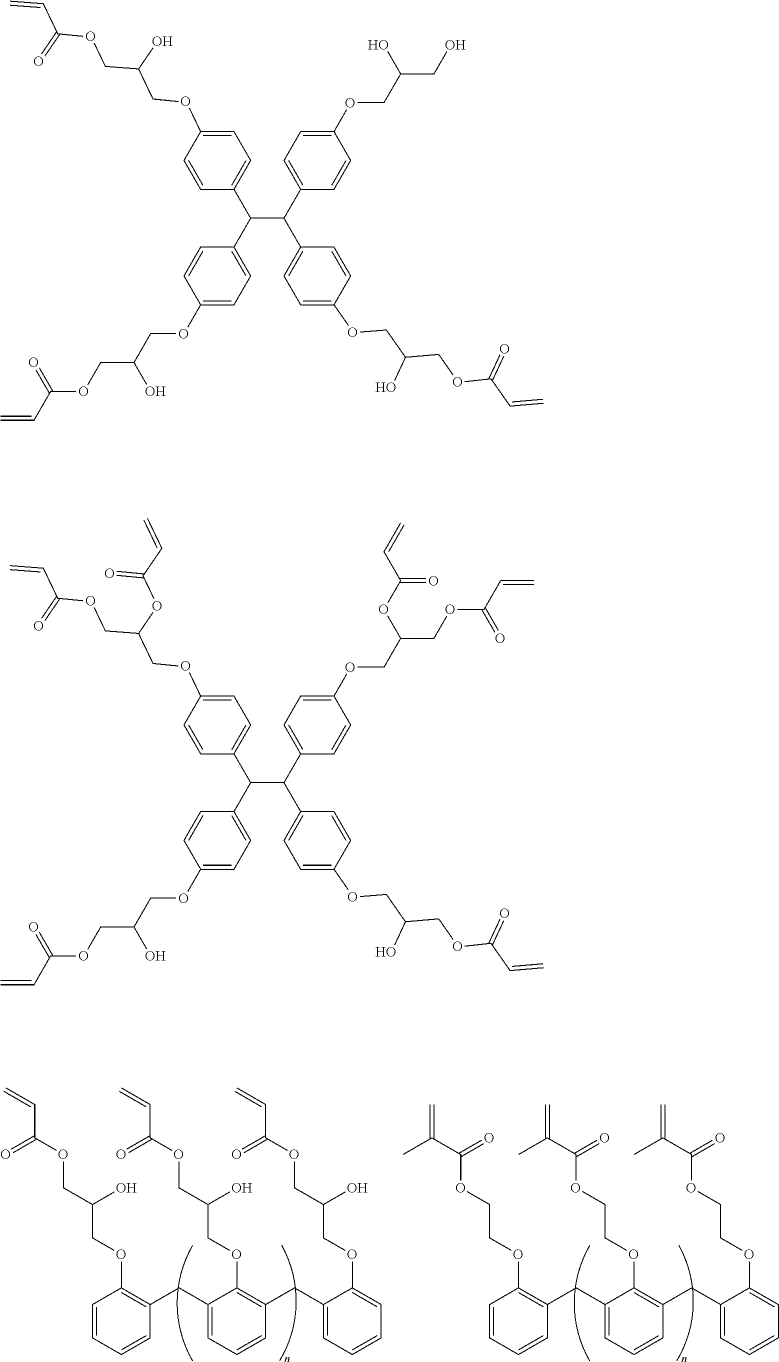

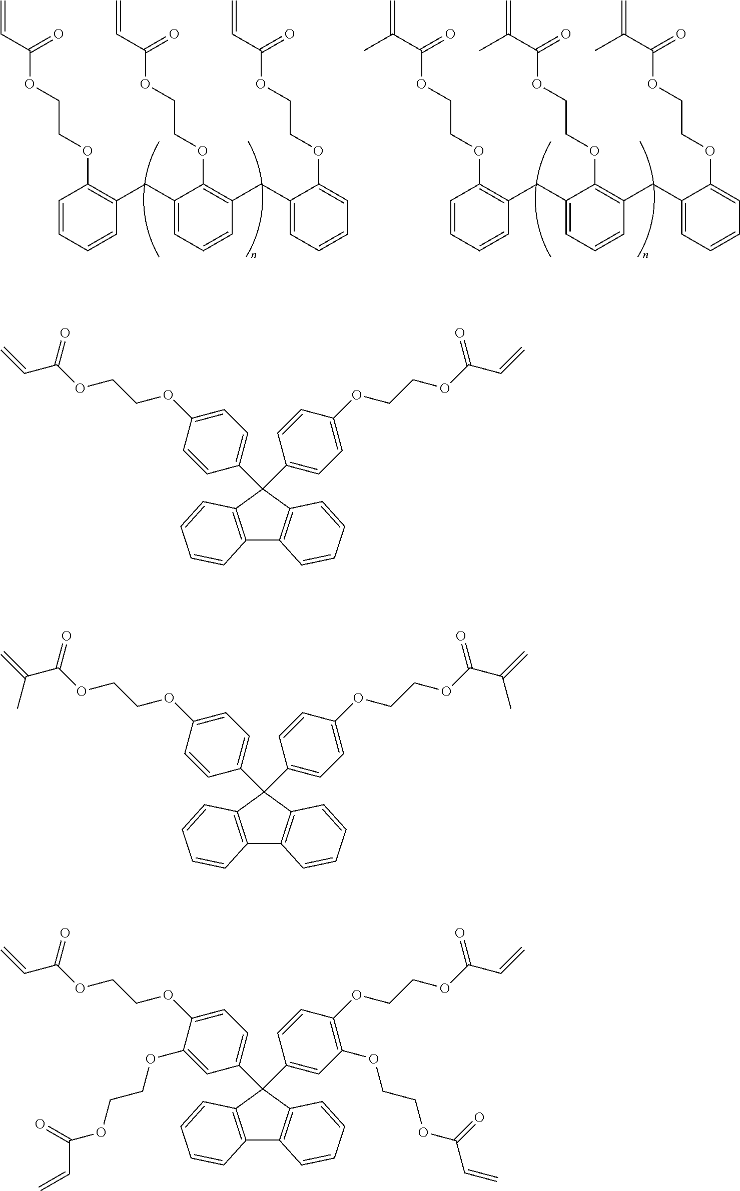

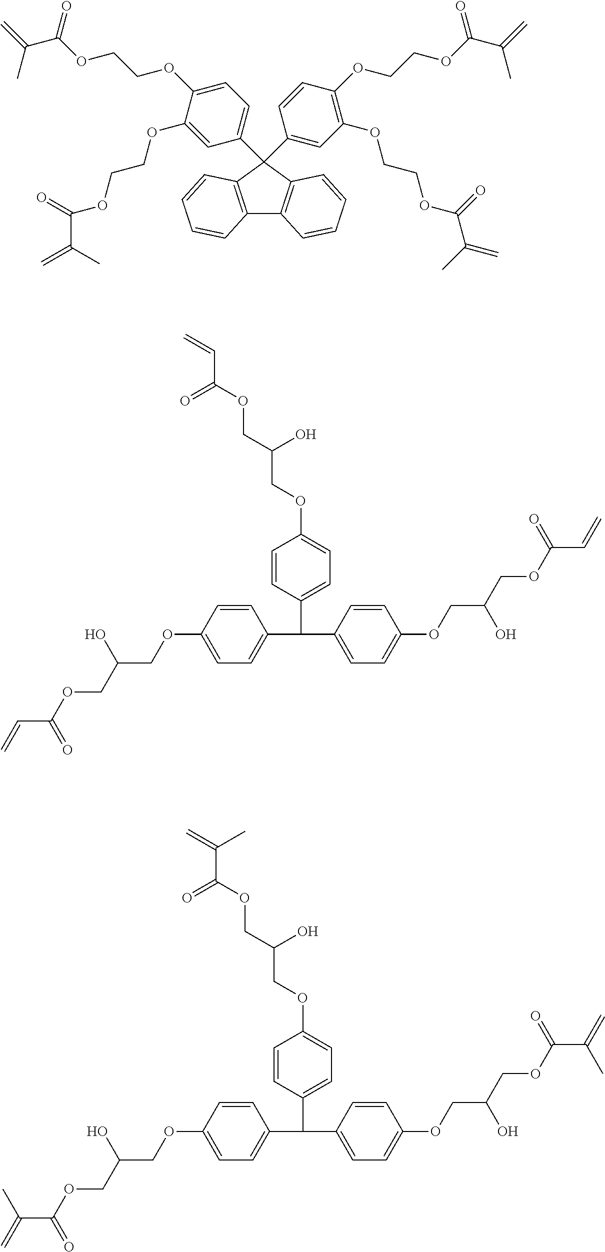

One (meth)acrylate having a carbon ring may be used or two or more (meth)acrylates having a carbon ring may be used.

As the (meth)acrylate having a carbon ring, a (meth)acrylate having a carbon ring produced by a production method known in the related art may be used or a commercially available product may be used. Examples of the commercially available product include A-B1206PE, ABE-300, A-BPE-10, A-BPE-20, A-BPE-30, A-BPE-4, A-BPEF, and A-DCP manufactured by Shin-Nakamura Chemical Co., Ltd., EBECRYL150 and IRR 214-K manufactured by Daicel-Allnex Ltd., and LIGHT ACRYLATE DCP-A, BP-4EAL, and BP-4PA manufactured by Kyoeisha Chemical Co., Ltd.

The amount of the (meth)acrylate having a carbon ring is preferably 40% to 95% by mass, more preferably 45% to 93% by mass, even more preferably 50% to 90% by mass, and particularly preferably 55% to 85% by mass with respect to the total mass of the solid contents (the remainder after volatilization of the volatile content) of the composition for forming a protective layer.

((Meth)Acrylic Polymer)

The (meth)acrylic polymer is a polymer of a monomer containing a derivative of (meth)acrylic acid. Examples of the derivative of (meth)acrylic acid include acrylic esters such as methyl acrylate, ethyl acrylate, and butyl acrylate, and methacrylic esters such as methyl methacrylate, ethyl methacrylate, and butyl methacrylate.

The (meth)acrylic polymer may be a homopolymer of one derivative of (meth)acrylic acid or a copolymer of two or more derivatives of (meth)acrylic acid or may be a copolymer with another monomer capable of copolymerizing with the above-described polymers. However, a copolymer of two or more derivatives of (meth)acrylic acid or a copolymer of another monomer and a derivative of (meth)acrylic acid is preferable.

Examples of a copolymerization component (another monomer) capable of copolymerizing with a derivative of (meth)acrylic acid include α,β-unsaturated acids such as acrylic acid and methacrylic acid, unsaturated acids such as unsaturated group-containing divalent carboxylic acids such as maleic acid, fumaric acid, and itaconic acid, aromatic vinyl compounds such as styrene, o-methyl styrene, m-methyl styrene, p-methyl styrene, 2,4-dimethyl styrene, p-ethyl styrene, p-tert-butyl styrene, α-methyl styrene, and α-methyl-p-methyl styrene, α,β-unsaturated nitriles such as acrylonitrile and methacrylonitrile, unsaturated carboxylic anhydrides such as a lactone ring unit, a glutaric anhydride unit, a glutarimide unit, and maleic anhydride, and maleimides such as maleimide, and N-substituted maleimide.

The weight-average molecular weight Mw of the (meth)acrylic polymer is preferably 20,000 or more and more preferably 25,000 or more from the viewpoint of mechanical strength. In addition, from the viewpoint of improving compatibility with an acrylic monomer, the weight-average molecular weight Mw of the (meth)acrylic polymer is preferably 600,000 or less and more preferably 300,0000 or less.

In the present specification, the weight-average molecular weight (hereinafter, abbreviated as Mw) is a value in terms of polystyrene measured by a gel permeation chromatography (GPC). The measurement conditions given below can be used as an example of specific measurement conditions of GPC.

GPC device: HLC-8320 (manufactured by Tosoh Corporation)

Columns: TSK gel Super HZM-H, TSK gel Super HZ4000, TSK gel Super HZ2000 employed in combination (manufactured by Tosoh Corporation, 4.6 mm inner diameter (ID)×15.0 cm)

Eluent: Tetrahydrofuran (THF)

The glass transition temperature Tg of the (meth)acrylic polymer is preferably 40° C. or higher and more preferably 60° C. or higher from the viewpoint of heat resistance. From the viewpoint of adhesiveness, the glass transition temperature is preferably 110° C. or lower and more preferably 100° C. or lower.

In the present specification, the glass transition temperature Tg (hereinafter, abbreviated as Tg) is calculated by a differential scanning calorimetry (DSC). The measurement conditions given below can be used as an example of specific measurement conditions of DSC.

DSC device: DSC 6200 manufactured by SII Technology, Inc.
Atmosphere in measurement room: nitrogen (50 mL/min)
Temperature increasing speed: 10° C./min
Measurement starting temperature: 0° C.
Measurement ending temperature: 200° C.
Sample pan: pan made of aluminum
Mass of measured sample: 5 mg
Calculation of Tg: an intermediate temperature between the decrease starting point and the decrease ending point in the DSC chart is set as Tg. Here, measurement is performed on the same sample two times and the second measurement result is adopted.

One (meth)acrylic polymer may be used or two or more (meth)acrylic polymers may be used.

As the (meth)acrylic polymer, a (meth)acrylic polymer produced by a known method may be used or a commercially available product may be used. Examples thereof include DELPET 60N and 80N (manufactured by Asahi Kasei Chemicals Corporation) and DIANAL BR80, BR83, BR85, BR88, BR110, and BR113 (manufactured by Mitsubishi Rayon Co., Ltd.).

The amount of the (meth)acrylic polymer is preferably 5% to 40% by mass, more preferably 7% to 35% by mass, and particularly preferably 10% to 30% by mass with respect to the total mass of the solid contents of the composition for forming a protective layer.

(Another Polymerizable Compound)

The composition for forming a protective layer may include another polymerizable compound other than the (meth)acrylate having a carbon ring. Examples of another polymerizable compound include polymerizable compounds used in the composition for forming an organic layer which will be described later, and a (meth)acrylate-based compound is preferable.

The amount of another polymerizable compound in the composition for forming a protective layer is preferably 0% to 10% by mass, more preferably 0% to 7% by mass, and even more preferably 0% to 5% by mass with respect to the total mass of the solid contents of the composition for forming a protective layer.

(Other Components)

The composition for forming a protective layer may further include a silane coupling agent, a polymerization initiator, a solvent, and the like. The silane coupling agent, the polymerization initiator, the solvent, and the like which are the same as those used in the composition for forming an organic layer which will be described later can be respectively used in the same amounts. For example, by the composition for forming a protective layer further containing a solvent, the composition for forming a protective layer becomes a composition suitable for coating.

[Organic Layer]

The gas barrier film of the present invention may include an organic layer. The organic layer may be provided between the inorganic layer that is in direct contact with the protective layer and the film substrate. The gas barrier film of the present invention may include two or more organic layers and the compositions of two or more organic layers may be the same as or different from each other.

The moisture content of the organic layer may be less than 1.0% or may be 1.0% or more. For example, the moisture content may be 1.0% to 3.0%.

The organic layer can be formed by curing the composition for forming an organic layer. The composition for forming an organic layer includes a polymerizable compound and may further include a polymerization initiator, a silane coupling agent, and the like.

The composition for forming an organic layer may be the same as or different from the composition for forming a protective layer. However, it is preferable that the composition for forming an organic layer is different from the composition for forming a protective layer.

For example, the amount of the (meth)acrylic polymer is preferably less than 10% by mass and more preferably less than 5% by mass with respect to the total mass of the solid contents of the composition for forming an organic layer. By setting the amount of the (meth)acrylic polymer to less than 5% by mass, a smooth inorganic layer can be formed on the organic layer.

(Polymerizable Compound)

The polymerizable compound is preferably a compound having an ethylenically unsaturated bond at a terminal or a side chain, and/or a compound having epoxy or oxetane at a terminal or a side chain. It is particularly preferable that the polymerizable compound is a compound having an ethylenically unsaturated bond at a terminal or a side chain. Examples of the compound having an ethylenically unsaturated bond at a terminal or a side chain include a (meth)acrylate-based compound, an acrylamide-based compound, and maleic anhydride. Among these, a (meth)acrylate-based compound is preferable, and an acrylate-based compound is particularly preferable.

As the (meth)acrylate-based compound, for example, (meth)acrylate, urethane (meth)acrylate, polyester (meth)acrylate, epoxy (meth)acrylate, or the like is preferable.

As the (meth)acrylate-based compound, specifically, for example, a compound described in paragraphs 0024 to 0036 of JP2013-43382A, a compound described in paragraphs 0036 to 0048 of JP2013-43384A, or a compound described in WO2013/047524 can be used. In the description of the composition for forming a protective layer, any of the above (meth)acrylates having a carbon ring may be used as the polymerizable compound in the composition for forming an organic layer.

The composition for forming an organic layer may include two or more polymerizable compounds.

The amount of the polymerizable compound (excluding the silane coupling agent) is preferably 60% by mass or more and more preferably 70% by mass or more with respect to the total mass of the solid contents (the remainder after volatilization of the volatile content) of the polymerizable composition.

(Polymerization Initiator)

The composition for forming an organic layer may include a polymerization initiator. In a case of using a polymerization initiator, the content thereof is preferably 0.1% by mole or more, more preferably 0.5% to 5% by mole of the total amount of the compounds involved in polymerization (polymerizable compounds). By adopting such a composition, a polymerization reaction via an active component generation reaction can be appropriately controlled. As the polymerization initiator, a photopolymerization initiator can be used and examples of the photopolymerization initiator include Irgacure series (for example, IRGACURE 651, IRGACURE 754, IRGACURE 184, IRGACURE 2959, IRGACURE 907, IRGACURE 369, IRGACURE 379, and IRGACURE 819), Darocure series (for example, DAROCURE TPO and DAROCURE 1173), and Quantacure PDO, all commercially available from BASF SE, and Esacure series (for example, ESACURE TZM, ESACURE TZT, and ESACURE KT046) all commercially available from Lamberti S.p.A.

(Silane Coupling Agent)

The composition for forming an organic layer may include a silane coupling agent. The silane coupling agent preferably has a hydrolyzable reactive group such as a methoxy group, an ethoxy group, or an acetoxy group, which is to be bonded to silicon, and a substituent which has one or more reactive groups selected from an epoxy group, a vinyl group, an amino group, a halogen group, a mercapto group, and a (meth)acryloyl group, as a substituent which is bonded to the same silicon. The silane coupling agent particularly preferably has a (meth)acryloyl group. Specific examples of the silane coupling agent include a silane coupling agent represented by Formula (1) described in WO2013/146069 and a silane coupling agent represented by Formula (I) described in WO2013/027786.

The proportion of the silane coupling agent in the total mass of the solid contents of the composition for forming an organic layer is preferably 0.1% to 30% by mass and more preferably 1.0% to 20% by mass.

(Solvent)

The composition for forming an organic layer may include a solvent. Examples of the solvent include ketones such as methyl ethyl ketone (MEK), or ester-based solvents: 2-butanone, propylene glycol monoethyl ether acetate (PGMEA), cyclohexanone, and a mixed solvent of any two or more solvents of these solvents. Among these, methyl ethyl ketone is preferable.

The content of the solvent in the composition for forming an organic layer is preferably 60% to 97% by mass and more preferably 70% to 95% by mass with respect to the total amount of the composition for forming an organic layer.

[Method of Preparing Organic Layer]

In order to prepare the organic layer, first, the composition for forming an organic layer is applied in the form of layer. In order to apply the composition in the form of layer, the composition for forming an organic layer may be applied on the film substrate. The application of the composition may be performed on the film substrate surface or the inorganic layer surface. Examples of the method for application include a dip coating method, an air knife coating method, a curtain coating method, a roller coating method, a wire bar coating method, a gravure coating method, a slide coating method, or an extrusion coating method (also referred to as a die coating method) using a hopper described in U.S. Pat. No. 2,681,294A and among these, an extrusion coating method can be preferably adopted

The composition for forming an organic layer may be dried as a coating film after the composition is applied.

The composition for forming an organic layer may be cured by light (such as ultraviolet rays), electron beams, or heat rays and is preferably cured by light. Particularly, it is preferable that while the composition for forming an organic layer is being heated at a temperature of 25° C. or higher (for example, 30° C. to 130° C.), the composition is cured. By promoting the free motion of the composition for forming an organic layer by heating, the composition can be effectively cured, and the film can be formed without damaging the film substrate or the like.

The light for irradiation may be ultraviolet rays using a high pressure mercury lamp or a low pressure mercury lamp as a light source. The irradiation energy is preferably 0.1 J/cm² or more and more preferably 0.5 J/cm² or more.

It is preferable that an oxygen concentration or oxygen partial pressure in the polymerization is set to be low since the polymerizable compound suffers polymerization inhibition by oxygen in the air. In a case of reducing the oxygen concentration at the time of the polymerization by a nitrogen substitution method, the oxygen concentration is preferably 2% or less and more preferably 0.5% or less. In a case where the oxygen partial pressure at the time of the polymerization is to be reduced by a pressure reducing method, the total pressure is preferably 1000 Pa or less and more preferably 100 Pa or less.

The polymerization rate of the polymerizable compound in the composition for forming an organic layer after curing is preferably 20% by mass or more, more preferably 30% by mass or more, and particularly preferably 50% by mass or more. The polymerization rate denoted here means a proportion of reacted polymerizable groups among all the polymerizable groups (such as acryloyl group and methacryloyl group) in the monomer mixture. The polymerization rate can be determined quantitatively by an infrared absorption method.

It is preferable that the organic layer is smooth and has a high film hardness. The smoothness of the organic layer is preferably less than 3 nm and more preferably less than 1 nm as an average roughness in 1 μm square (Ra value).

Although the film thickness of the organic layer is not particularly limited, from the viewpoint of brittleness and light transmittance, the film thickness is preferably 50 nm to 5000 nm and more preferably 200 nm to 3500 nm.

It is required that foreign matter such as particles and protrusions are not present on the surface of the organic layer. Therefore, it is preferable that the organic layer is formed in a clean room. The degree of cleanliness is preferably class 10000 or lower and more preferably class 1000 or lower.

It is preferable that the hardness of the organic layer is high. In a case where the hardness of the organic layer is high, a smooth inorganic layer is formed. As a result, it is found that the barrier capability is improved. The hardness of the organic layer can be denoted as a microhardness based on the nanoindentation method. The microhardness of the organic layer is preferably 100 N/mm or higher and more preferably 150 N/mm or higher.

(Lamination of Organic Layer and Inorganic Layer)

Lamination of an organic layer and an inorganic layer can be conducted by successively and repeatedly forming an organic layer and an inorganic layer based on a desired layer configuration.

<Organic Electronic Device>

The gas barrier film of the present invention can be preferably used in an organic electronic device of which the performance is deteriorated by chemical components in air (oxygen, water, nitrogen oxides, sulfur oxides, ozone, and the like). Examples of the organic electronic device include organic electroluminescence devices, liquid crystal display devices, thin film transistors, touch panels, electronic papers, and solar cells. The gas barrier film of the present invention can be preferably used for a substrate for an organic electronic element for providing an organic electronic element or a sealing member for sealing an organic electronic element in an organic electronic device.

[Organic Electroluminescence Device]

The organic electroluminescence device has a structure including a substrate, an organic electroluminescent element, and a sealing member in this order in a thickness direction of the substrate. In the present specification, the term “organic electroluminescence device” refers to “organic EL device” and the term “organic electroluminescent element” refers to an “organic EL element”. The gas barrier film of the present invention can be preferably used for a substrate for providing the organic electroluminescent element or a sealing member for sealing the organic electroluminescent element in the organic electroluminescence device.

The organic electroluminescence device preferably includes a substrate, an organic electroluminescent element provided on the substrate, and a gas barrier film in this order, and the surface of the gas barrier film on the organic electroluminescent element side is a protective layer.

In the substrate for an organic electroluminescence device using the gas barrier film of the present invention as a substrate, adhesiveness between the gas barrier film and the organic electroluminescent element is good. Particularly, for example, even in a case where a material for forming an electrode is formed on the surface of the protective layer of the gas barrier film of the present invention, adhesiveness with a layer to be formed is good.

As one sealing method for the organic electroluminescent element, a solid sealing method may be used. This method is a method in which a protective layer is formed on an organic electroluminescent element on a substrate, and then an adhesive layer and a gas barrier film are laminated and cured. The protective layer of the gas barrier film of the present invention exhibits good adhesiveness with an adhesive layer. An adhesive for forming the adhesive layer is not particularly limited, and examples thereof include a thermosetting epoxy resin, a photocurable epoxy resin, and a photocurable acrylate resin. Among these, from the viewpoint in which water vapor transmission is not easy, a photocurable epoxy resin is preferable.

Examples of the organic EL device in which the gas barrier film is used are described in detail in JP2007-30387A. In addition, in an organic TFT device, the gas barrier film can be incorporated in the device as a gas barrier film also functioning as a λ/4 plate.

(Organic Electroluminescent Element)

The organic electroluminescent element is configured to include an electrode which becomes a cathode, an electrode which becomes an anode and further include an organic electroluminescent layer between the two electrodes.

Regarding the electrodes in the organic electroluminescence device, either of one electrode which is arranged on the substrate side and one electrode which is arranged on the sealing member side may be a reflecting electrode and the other electrode may be a transparent electrode. It is also preferable that one electrode which is arranged on the substrate side is a transparent electrode and the other electrode which is arranged on the sealing member side is a reflecting electrode.

The organic electroluminescent layer may have at least a light emitting layer and further have functional layers other than the light emitting layer. Examples of the functional layers included in the organic electroluminescence layer include a hole transport layer, an electron transport layer, a hole blocking layer, an electron blocking layer, a hole injection layer, and an electron injection layer.

Regarding materials for preparing the organic electroluminescent layer, and each layer and each electrode in the organic electroluminescent layer, configurations, lamination order, and the configuration of the organic electroluminescence device, the description of paragraphs 0081 to 0122 of JP2012-155177A can be referred to.

In the organic electroluminescent element, the anode is preferably formed by coating. The anode also may be formed by printing. The anode can be formed by applying a conductive ink including a metal such as silver, aluminum, gold, or copper or a composition including an organic conductive polymer. Out of these, the anode is preferably formed by applying a composition including an organic conductive polymer. Examples of the organic conductive polymer include organic conductive polymers described in paragraphs 0015 to 0020 of JP2014-197500A. The anode may include polystyrene sulfonic acid, polyvinyl sulfonic acid, or the like as a dopant. As a method of forming the anode, the description regarding a method of forming a conductive film in paragraphs 0035 to 0043 of JP2014-197500A can be referred to.

In addition, a wiring in paragraph 0055 of JP2014-197500A is also preferably provided between the anode and the substrate. The wiring may be a wiring having resistance lower than that of the anode. The wiring may include a metal such as silver, aluminum, gold, or copper. The wiring can be formed by vacuum-depositing the metal and performing etching using a photolithography or a mask. In addition, wiring can also be formed by printing or applying a conductive ink including the metal.

(Substrate and Sealing Member)

The respective shapes and the sizes of the substrate and the sealing member are not particularly limited and can be appropriately selected according to the purposes. The shape may be, for example, a flat plate shape or the like. As the structure, a single layer structure may be adopted or a laminated structure may be adopted. The size can be appropriately selected according to the size of a functional laminating material or the like. As at least any one selected from the substrate and the sealing member, the gas barrier film of the present invention is used. The outermost surface of the gas barrier film on the organic electroluminescent element side may be set to the protective layer. As any one selected from the substrate and the sealing member, an inorganic material such as glass (as alkali-free glass and soda lime glass) may be used.

### EXAMPLES

The present invention is described with greater specificity below through Examples. The materials, amounts used, ratios, processing contents, processing procedures, and the like that are indicated in the Examples below can be suitably modified without departing from the spirit of the present invention. Accordingly, the scope of the present invention is not limited by the specific examples given below.

### Example 1

(Preparation of Composition for Forming Protective Layer)

A composition for forming a protective layer was prepared with the following formulation. The solid content concentration was set to 15% by mass.

| | |
|---|---|
| P1: acrylic polymer (DIANAL BR113, | 6.0 parts by mass |
| manufactured by Mitsubishi Rayon Co., Ltd., | |
| weight-average molecular weight: 30000) | |
| A1: 9,9-bis[4-(2-acryloyloxyethoxy)phenyl]fluo- | 17.7 parts by mass |
| rene (NK ESTER A-BPEF, manufactured by | |
| Shin-Nakamura Chemical Co., Ltd.) | |
| Silane coupling agent 1: KBM 5103 | 6.0 parts by mass |
| (manufactured by Shin-Etsu Chemical Co., Ltd.) | |
| Ultraviolet polymerization initiator 1: ESACURE | 0.5 parts by mass |
| KTO46 (manufactured by Lamberti S.p.A.) | |
| 2-Butanone | 169.8 parts by mass |

(Measurement of Moisture Content of Protective Layer)

After 10 g of the composition for forming a protective layer was placed onto a petri dish and dried at 80° C. for 5 minutes, the composition was cured by being irradiated with ultraviolet rays from a high pressure mercury lamp (at a cumulative irradiation dose of about 600 mJ/cm²) in a chamber in which the oxygen concentration was set to 0.1% by a nitrogen substitution method. The obtained cured article was dried overnight in a vacuum oven at 0.133 Pa (1×10⁻³ torr) and 110° C. The moisture content in a case where the cured article was left to stand under an environment of 25° C. and 50% RH for 3 days was measured by a Karl Fischer method to calculate the moisture content of the protective layer. Regarding the Karl Fischer method, evaluation was performed based on the following standard according to the description of JIS K0113.

A: The moisture content was less than 0.5%.

B: The moisture content was 0.5% or more and less than 1.0%.

C: The moisture content was 1.0% or more.

(Preparation of Barrier Film)

A gas barrier film having a substrate, a first organic layer, a first inorganic layer, a second organic layer, a second inorganic layer, and a protective layer was prepared.

As the substrate, a PET film (A4300, manufactured by Toyobo Co., Ltd.) having a thickness of 100 μm was prepared.

28.5 g of trimethylol propane triacrylate (TMPTA, manufactured by Daicel-Allnex Ltd.), 1.5 g of an ultraviolet polymerization initiator (ESACURE KT046, manufactured by Lamberti S.p.A.), and 170 g of 2-butanone (manufactured by Wako Pure Chemical Industries, Ltd.) were mixed to prepare a coating (composition for forming a first organic layer) for forming a first organic layer. The solid content concentration of the coating was 15% by mass.

The prepared coating was applied to the surface of the prepared substrate (PET film). The application was performed using a die coater such that the film thickness of the first organic layer became 1 μm. After the application, the coating on the substrate was dried in an oven at 80° C. for 3 minutes.

Next, the coating was cured by being irradiated with ultraviolet rays from a high pressure mercury lamp (at a cumulative irradiation dose of about 600 mJ/cm²) in a chamber in which the oxygen concentration was set to 0.1% by a nitrogen substitution method to obtain a first organic layer.

On the first organic layer, a silicon nitride film having a film thickness of 40 nm was formed to obtain a first inorganic layer.

The first inorganic layer was formed by using a capacitively coupled plasma (CCP)-CVD device (manufactured by Samco Inc.). As a material gas, silane gas (flow rate: 160 sccm: a standard condition at 0° C. and 1 atmospheric pressure, hereinafter the same will be applied), ammonia gas (flow rate: 370 sccm), hydrogen gas (flow rate: 590 sccm), and nitrogen gas (flow rate: 240 sccm) were used. The film forming pressure was set to 40 Pa. A power source of high frequency of 13.56 MHz frequency was used as a power source, and the plasma excitation power was set to 2.5 kW.

The second organic layer was formed on the first inorganic layer.
21.5 g of TMPTA (manufactured by Daicel-Allnex Ltd.), 5.5 g of KBM-5103 (manufactured by Shin-Etsu Chemical Co., Ltd.), 1.0 g of KAYAMER PM-21 (manufactured by Nippon Kayaku Co., Ltd.), 1.5 g of an ultraviolet polymerization initiator (ESACURE KTO46, manufactured by Lamberti S.p.A.), and 170 g of 2-butanone (manufactured by Wako Pure Chemical Industries, Ltd.) were mixed to prepare a coating (composition for forming a second organic layer) for forming a second organic layer. The solid content concentration of the coating was 15% by mass.

A second organic layer having a film thickness of 1 μm was formed on the first inorganic layer in the same manner as in the formation of the first organic layer using the prepared coating.

In addition, a silicon nitride film having a film thickness of 40 nm was formed on the second organic layer in the same manner as in the formation of the first inorganic layer to obtain a second inorganic layer.

Further, a protective layer having a film thickness of 1.0 μm was formed on the second inorganic layer in the same manner as in the formation of the first organic layer using the composition for forming a protective layer.

Thus, a gas barrier film having the first organic layer, the first inorganic layer, the second organic layer, the second inorganic layer, and the protective layer on the surface of the substrate was obtained.

As a result of measuring the gas barrier properties of the obtained gas barrier film (water vapor transmission rate) by a calcium corrosion method (a method described in JP2005-283561A), the water vapor transmission rate was 1×10⁻⁵ g/(m²·day).

(Solvent Resistance)

The obtained gas barrier film was immersed in xylene for 30 seconds and the solvent resistance was evaluated from a difference between the haze values before and after immersion based on the following standard.

The haze value was measured by using an ultraviolet visible spectrophotometer (NGH-5000, manufactured by Nippon Denshoku Industries Co., Ltd.) according to JIS K7136.

A: The difference between the haze values before and after immersion was less than 0.2%.

B: The difference between the haze values before and after immersion was 0.2% or more and less than 1.0%.

C: The difference between the haze values before and after immersion was 1.0% or more.

(Adhesiveness with Inorganic Layer)

The adhesiveness of the protective layer with respect to the second inorganic layer was evaluated by a cross-cut peeling test according to JIS K5400.

The surface of the obtained gas barrier film was cut with a cutter knife at an angle of 90° to the film surface at intervals of 1 mm to prepare a lattice pattern formed of 100 film pieces at intervals of 1 mm. A 2 cm-width Mylar Tape (polyester tape No. 31B, manufactured by Nitto Denko Corporation) was attached thereto and the tape was peeled off in a direction at 90° with respect to the film surface three times. The number of film pieces of the protective layer that remained was counted and the counted number was evaluated based on the following standard.

A: The number of film pieces of the remained protective layer was 100.

B: The number of film pieces of the remained protective layer was 91 to 99.

C: The number of film pieces of the remained protective layer was 90 or less.

(Scratch Resistance)

The scratch resistance of the protective layer was evaluated by a scratch test using a sapphire needle according to JIS K5600-5-5.

The test was performed with a continuous loading scratching intensity tester (TYPE: 18/18L, manufactured by HEIDON) using a sapphire needle having a diameter of 0.05 mm and evaluation was performed by a scratch starting load based on the following standard.

A: The scratch starting load was 20 g or greater.

B: The scratch starting load was 15 g or greater and less than 20 g.

C: The scratch starting load was less than 15 g.

(Preparation of Organic Electroluminescent Element)

The gas barrier film cut into a size of 40 mm square was prepared as a substrate. An Al film having a film thickness of 200 nm was deposited on the surface of the protective layer of the gas barrier film as a lead-out electrode.

Poly(3,4-ethylenedioxythiophene)/polystyrene sulfonic acid (PEDOT.PSS, Orgacon 5305, manufactured by Sigma-Aldrich Co. LLC.) was applied thereto using a spin coater to have a film thickness of 100 nm. The coating film was dried in an oven at 130° C. for 30 minutes to form an anode. Sequentially, α-NPD:Bis[N-(1-naphthyl)-N-phenyl]benzidine was deposited on the surface of the formed anode to form a hole transport layer having a film thickness of 29 nm, a light emitting layer doped with 5% Ir(ppy)₃(Tris(2-phenylpyridinato)iridium) using CBP(4,4′-Bis(carbazol-9-yl)biphenyl) as a host material was formed by deposition to have a film thickness of 20 nm, BAlq(Bis-(2-methyl-8-quinolinolato)-4-(phenyl-phenolate)-aluminium(III)) was deposited to form a hole blocking layer having a film thickness of 10 nm. Then, Alq₃(Tris(8-hydroxy-quinolinato)aluminium) was deposited to form an electron transport layer having a film thickness of 20 nm. Thus, an organic electroluminescent layer was formed.

Subsequently, a LiF film having a film thickness of 0.5 nm and an Al film having a film thickness of 100 nm were deposited on the surface of the obtained organic electroluminescent layer in this order to form a cathode. Thus, an organic electroluminescent element was formed on the surface of the gas barrier film.

(Preparation of Organic EL Device)

An adhesive (XNR-5516Z, manufactured by Nagase ChemteX Corporation) was applied to cap glass for sealing with a size of 33 mm square using a dispenser. In the nitrogen atmosphere, the organic electroluminescent element was sealed with the cap glass to which the adhesive was applied. The adhesive was cured by being irradiated with ultraviolet rays from a metal halide lamp (at a cumulative irradiation dose of about 6 J/cm²) to form an organic EL device.

(Durability Evaluation)

The organic EL device was left to stand in an oven at 60° C. for 500 hours. To evaluate the moisture containing (outgas) effect of the protective layer, evaluation was performed under the environment in which moisture permeation from the outside of the organic EL device is suppressed as much as possible.

The organic EL device after being left to stand was emitted light upon application with a voltage of 7 V using a source measure unit (SMU 2400 model, manufactured by Keithley Instruments, Inc.). The light emitting surface was observed using a microscope and the total area of dark spots with respect to the area of the light emitting surface was evaluated based on the following standard.

A: The total area of dark spots was less than 5%.

B: The total area of dark spots was 5% to 20%.

C: The total area of dark spots was 20% or more.

### Examples 2 to 6 and Comparative Examples 1 to 3

The preparation of the barrier film, the preparation of the organic EL device, and evaluation thereof were performed in the same manner as in Example 1 except that instead of using the composition for forming a protective layer of Example 1, the following composition for a protective layer was used. The results are shown in Table 1.

### Example 2

| | |
|---|---|
| P2: Acrylic polymer (DIANAL BR110, | 6.0 parts by mass |
| manufactured by Mitsubishi Rayon Co., Ltd., | |
| weight-average molecular weight: 72000) | |
| A1 | 17.7 parts by mass |
| Silane coupling agent 1 | 6.0 parts by mass |
| Ultraviolet polymerization initiator 1 | 0.5 parts by mass |
| 2-Butanone | 169.8 parts by mass |

### Example 3

| | |
|---|---|
| P1 | 6.0 parts by mass |
| A2: Ethoxylated bisphenol A diacrylate (NK | 17.7 parts by mass |
| ESTER A-BPE-4, manufactured by | |
| Shin-Nakamura Chemical Co., Ltd.) | |
| Silane coupling agent 1 | 6.0 parts by mass |
| Ultraviolet polymerization initiator 1 | 0.5 parts by mass |
| 2-Butanone | 169.8 parts by mass |

### Example 4

| | |
|---|---|
| P1 | 6.0 parts by mass |
| A3: Tricyclodecane dimethanol diacrylate | 17.7 parts by mass |
| (NK ESTER A-DCP, manufactured by | |
| Shin-Nakamura Chemical Co., Ltd.) | |
| Silane coupling agent 1 | 6.0 parts by mass |
| Ultraviolet polymerization initiator 1 | 0.5 parts by mass |
| 2-Butanone | 169.8 parts by mass |

### Example 5

| | |
|---|---|
| P1 | 3.0 parts by mass |
| A1 | 20.7 parts by mass |
| Silane coupling agent 1 | 6.0 parts by mass |
| Ultraviolet polymerization initiator 1 | 0.5 parts by mass |
| 2-Butanone | 169.8 parts by mass |

### Example 6

| | |
|---|---|
| P1 | 9.0 parts by mass |
| A1 | 14.7 parts by mass |
| Silane coupling agent 1 | 6.0 parts by mass |
| Ultraviolet polymerization initiator 1 | 0.5 parts by mass |
| 2-Butanone | 169.8 parts by mass |

### Comparative Example 1

| | |
|---|---|
| P1 | 6.0 parts by mass |
| A4: Polyethylene glycol diacrylate | 17.7 parts by mass |
| (NK ESTER A-200, manufactured by | |
| Shin-Nakamura Chemical Co., Ltd.) | |
| Silane coupling agent 1 | 6.0 parts by mass |
| Ultraviolet polymerization initiator 1 | 0.5 parts by mass |
| 2-Butanone | 169.8 parts by mass |

### Comparative Example 2

| | |
|---|---|
| P1 | 6.0 parts by mass |
| A5: Trimethylol propane triacrylate (TMPTA, | 17.7 parts by mass |
| manufactured by Daicel-Allnex Ltd.) | |
| Silane coupling agent 1 | 6.0 parts by mass |
| Ultraviolet polymerization initiator 1 | 0.5 parts by mass |
| 2-Butanone | 169.8 parts by mass |

### Comparative Example 3

| | |
|---|---|
| P3: Styrene polymer (manufactured by | 6.0 parts by mass |
| Sigma-Aldrich Co. LLC., weight-average | |
| molecular weight: 35000) | |
| A1 | 17.7 parts by mass |
| Silane coupling agent 1 | 6.0 parts by mass |
| Ultraviolet polymerization initiator 1 | 0.5 parts by mass |
| 2-Butanone | 169.8 parts by mass |

TABLE 1

| | Composition | | | | | | | |
|---|---|---|---|---|---|---|---|---|
| | | | Proportion | | | | | |
| | | | of polymer | | | | | |
| | | | with | Protective | Gas barrier film | | | Organic |
| | | | respect to | layer | Solvent | | | EL |
| | | | total solid | Moisture | resistance | Adhesiveness | | Organic |
| | | | content | content | Δ haze | with inorganic | Scratch | EL |
| | Acrylate | Polymer | (%) | (%) | (%) | layer | resistance | durability |
| Example 1 | A1 | P1 | 20 | A | A | A | A | A |
| Example 2 | A1 | P2 | 20 | A | A | A | A | A |
| Example 3 | A2 | P1 | 20 | B | A | A | B | B |
| Example 4 | A3 | P1 | 20 | A | A | A | A | A |
| Example 5 | A1 | P1 | 10 | A | A | B | A | A |
| Example 6 | A1 | P1 | 30 | B | B | A | B | B |
| Comparative | A4 | P1 | 20 | C | A | A | C | C |
| Example 1 | | | | | | | | |
| Comparative | A5 | P1 | 20 | C | A | C | A | C |
| Example 2 | | | | | | | | |
| Comparative | A1 | P3 | 20 | A | C | A | A | A |
| Example 3 | | | | | | | | |

What is claimed is:

1. A gas barrier film comprising, in order:
a film substrate;
an inorganic layer; and
a protective layer that is in direct contact with the inorganic layer and is provided on a surface of the inorganic layer,
wherein the protective layer is a layer formed by curing a composition including a (meth)acrylate having a carbon ring and a (meth)acrylic polymer.

2. The gas barrier film according to claim 1,
wherein the (meth)acrylate has two or more (meth)acryloyl groups.

3. The gas barrier film according to claim 1,
wherein the (meth)acrylate has a fluorene ring.

4. The gas barrier film according to claim 1,
wherein a weight-average molecular weight of the (meth)acrylic polymer is 20,000 or more and 600,000 or less.

5. The gas barrier film according to claim 1,
wherein an amount of the (meth)acrylic polymer is 5% to 40% by mass with respect to a total mass of solid contents of the composition.

6. The gas barrier film according to claim 1,
wherein an amount of the (meth)acrylic polymer is 10% to 30% by mass with respect to a total mass of solid contents of the composition.

7. The gas barrier film according to claim 1,
wherein the composition includes a silane coupling agent.

8. The gas barrier film according to claim 1,
wherein a film thickness of the protective layer is 0.1 to 2.0 μm.

9. The gas barrier film according to claim 1,
wherein the inorganic layer includes oxynitride silicon or silicon nitride.

10. The gas barrier film according to claim 1, further comprising:
at least one organic layer between the film substrate and the inorganic layer.

11. The gas barrier film according to claim 1,
wherein at least two organic layers and at least two inorganic layers are provided, and
the film substrate, one organic layer, one inorganic layer, the other organic layer, the other inorganic layer, and the protective layer are provided in this order.

12. An organic electronic device comprising:
the gas barrier film according to claim 1.

13. A substrate for an organic electroluminescence device comprising:
the gas barrier film according to claim 1; and
an organic electroluminescent element that is in direct contact with the protective layer.

14. The substrate for an organic electroluminescence device according to claim 13,
wherein the organic electroluminescent element includes an anode, a light emitting layer, and a cathode in this order, and
the anode is formed by coating.

15. An organic electroluminescence device comprising:
the substrate for an organic electroluminescence device according to claim 13.

16. An organic electroluminescence device comprising, in order:
a substrate;
an organic electroluminescent element that is provided on the substrate; and
the gas barrier film according to claim 1,
wherein a surface of the gas barrier film on an organic electroluminescent element side is the protective layer.
